(19) United States
(12) Patent Application Publication
(10) Pub. No.: US 2026/0322343 A1
(43) Pub. Date: Oct. 15, 2026

(54) LC INTERFACING FILTER INCORPORATING A DAMPING CIRCUIT

(71) Applicant: SAFRAN ELECTRICAL & POWER, Blagnac Cedex (FR)

(72) Inventor: Eric DE WERGIFOSSE, Blagnac Cedex (FR)

(73) Assignee: SAFRAN ELECTRICAL & POWER, Blagnac Cedex (FR)

(21) Appl. No.: 19/478,111

(22) PCT Filed: Apr. 19, 2024
(86) PCT No.: PCT/FR2024/050514

§ 371 Date: Oct. 23, 2025

(30) Foreign Application Priority Data
Apr. 28, 2023 (FR) FR2304342

(51) Int. Cl. H03H 7/01

(52) U.S. Cl. CPC H03H 7/0115

(57) ABSTRACT

LC interfacing filter including a parallel capacitor and a serial inductance including eddy current magnetic losses, the inductance being configured so that the eddy current magnetic losses outweigh the hysteresis losses, the inductance consisting of a magnetic material tube around which an electrical conductor is wound, with an insulating sheet separating the magnetic material tube from the electrical conductor.

### TECHNICAL FIELD

The present invention relates to the field of differential-mode filtering in high-power electrical supply networks, comprising in particular energy converters.

### PRIOR ART

When a (switching or non-switching) energy converter, acting as a load or as a generator, must be connected to an electrical supply network, it is necessary to insert an interfacing filter whose aim will be to reduce the current ripples to a lower level than the one specified by the supply network standard and thus preserve its quality in terms of voltage ripples. The filter must further be designed so as not to compromise the stability of the electrical network.

Conventionally, this filter focuses on a parallel capacitor and a serial inductance, with the level of attenuation of the harmonic content of the current to be rejected directly depending on the ratio of the impedances of these two passive elements L and C. However, such an LC filter is unstable and, in practice, cannot be used without the addition of a damping circuit dimensioned to achieve a certain damping ratio, defined depending on the needs of the application. The damping ratio is a dimensionless quantity characterizing the evolution and decay over time of the oscillations of a physical system.

Note that the addition of the damping circuit affects the impedance ratio, thus requiring the correction of the values of L and/or C if it is wished to maintain a constant attenuation level defined initially. It should also be noted that the conventional damping circuits are poorly adapted to the high-voltage direct current (HVDC) networks whose impedance seen by the filter is not constant (switchable sources and/or loads, for example) and for which the only solution is to very significantly multiply the size of the filters in order to make the variations in the network impedance as small as necessary in relative value.

It is known to achieve the damping circuit of an LC filter using several topologies, essentially classified according to two types of structures: the parallel structures where the damping circuit acts on the impedance of the parallel capacitor and the serial structures where the damping circuit acts on the impedance of the serial inductance. These topologies can also be classified according to the order of the filter (the number of additional L or C elements).

The second-order parallel or serial structures have the disadvantage of requiring, in addition to the elements L and C, an additional power resistance whose dissipation will be prohibitive and will most often require specific cooling, while the third-order structures have the disadvantage of having a low damping ratio, typically less than 0.2 if it is not wished to significantly affect the dimensioning of the filter. Indeed, a damping ratio of 0.5 involves adding, for damping purposes, a capacitor or an inductance that is 3 times the value of the initial element L or C of the filter, thus multiplying by 4 the size and therefore the weight of the filter with its damping circuit.

Moreover, the lower the damping ratio (<0.2), the greater the accuracy constraint on the filter components to guarantee this damping level. The required tolerance on the value of the components can then become a serious problem and must be taken into account when a low damping is chosen to avoid the mass penalties that accompany the higher damping values.

### DISCLOSURE OF THE INVENTION

The main aim of the present invention is therefore to propose a filter incorporating damping that overcomes the aforementioned drawbacks. Another aim of the invention is to obtain a filter with a constant damping ratio over a wide frequency range.

These aims are achieved by an LC interfacing filter including a parallel capacitor and a serial inductance including eddy current magnetic losses, characterized in that the inductance is configured so that the eddy current magnetic losses outweigh the hysteresis losses, and in that the inductance consists of a magnetic material tube around which an electrical conductor is wound, with an insulating sheet separating the magnetic material tube from the electrical conductor.

Thus, by incorporating the damping function of the filter within the inductance itself of the filter, it is possible to avoid the usual resource to the power resistances conventionally used to form the damping circuit.

Preferably, the electrical conductor is wound inside the magnetic material tube instead of around it.

According to another embodiment, the LC interfacing filter including a parallel capacitor and a serial inductance including eddy current magnetic losses is characterized in that the inductance is configured so that the eddy current magnetic losses outweigh the hysteresis losses and in that the inductance consists of several magnetic material tubes placed side by side and around which an electrical conductor is wound, with an insulating tube or an insulating sheet separating the magnetic material tubes from the electrical conductor.

Preferably, the number of magnetic material tubes is comprised between 2 and 100.

Advantageously, the magnetic material tubes are identical.

Preferably, the magnetic material tubes are disposed around the wound electrical conductor instead of being inside it.

Advantageously, the magnetic material tube(s) each include a wall with slots or orifices.

Preferably, the magnetic material tube(s) each have a circular, square or polygonal profile.

Advantageously, the eddy current magnetic losses are created by the skin effect if it is sought to obtain a constant damping ratio over a wide frequency range.

Preferably, the magnetic material of the magnetic material tube(s) is an ordinary magnetic steel if the frequency range where the damping must be located is less than about 1 MHz.

### BRIEF DESCRIPTION OF THE DRAWINGS

Other characteristics and advantages of the present invention will emerge from the description given below, with reference to the appended drawings which illustrate one exemplary embodiment thereof without any limitation and in which:

FIG. 1 illustrates the equivalent electrical diagram of an LC filter with a damper in accordance with the invention,

FIGS. 2 and 2A show a first exemplary embodiment of the inductance of the filter in FIG. 1,

FIG. 3 shows a second exemplary embodiment of the inductance of the filter in FIG. 1,

FIG. 4 shows a third exemplary embodiment of the inductance of the filter in FIG. 1,

FIG. 5 shows the variation, as a function of frequency, of the equivalent serial inductance of the inductance in FIG. 2, and

FIG. 6 shows the variation, as a function of frequency, of the equivalent serial resistance of the inductance in FIG. 2,

FIG. 7 shows the variation, as a function of frequency, of the damping ratio of the inductance in FIG. 2.

### DESCRIPTION OF THE EMBODIMENTS

The principle of the invention is based on obtaining the damping of the LC filter by creating controlled and predictable magnetic losses at the level of the magnetic circuit of the inductance of the filter, so as to ensure by design the damping ratio of the filter.

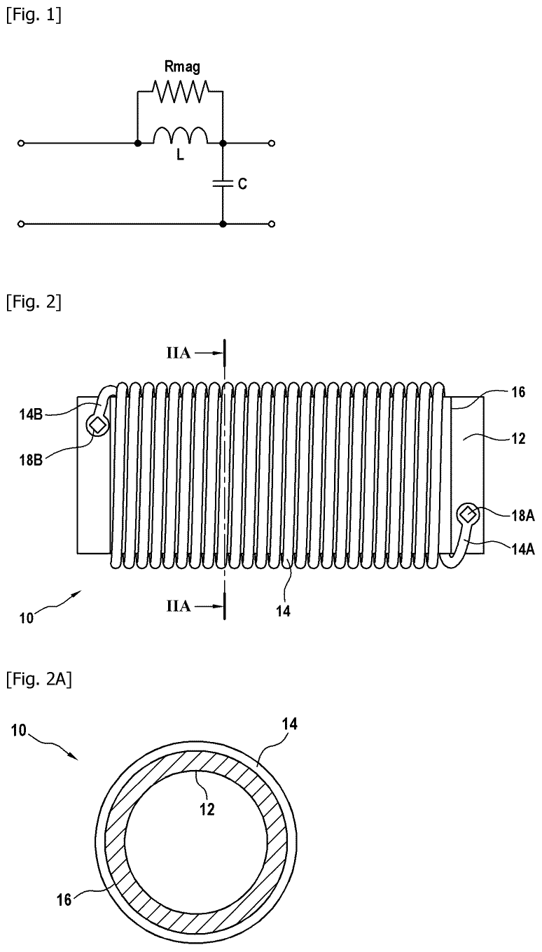

Thus, and as illustrated in FIG. 1, the damping circuit is not achieved by adding one or more power resistances associated or not associated with other passive components, such as a capacitor in the case of a parallel damping or an inductance in the case of a serial damping, as these power resistances generate mass and volume and often require specific cooling for the power circuits. Rather, it is achieved by the magnetic losses (represented by its electrical equivalent Rmag in parallel with the inductance L) that can be created at the level of the magnetic circuit of the inductance L of the LC filter.

To create magnetic losses, it is known to act on the eddy current losses and/or on the hysteresis losses. However, in order to avoid excessive sensitivity to the fine characteristics of the materials that can be subject to significant manufacturing dispersions, the magnetic circuit of the inductance is designed to make the eddy current losses largely outweighing the hysteresis losses (typically 10 to 100 times greater) and to make them evolve in a substantially constant manner over a wide frequency range, typically between 100 Hz and several hundred kHz, or even 1 MHz. To do so and to address this dual issue, the eddy current losses are created by skin effect.

The skin effect is an electromagnetic phenomenon that, at a high frequency, causes the current to circulate only on the surface of the conductors. This phenomenon of electromagnetic origin, which exists for all the conductors through which alternating currents pass, causes the decay of the current density as moving away from the periphery of the conductor. More specifically, the more the frequency f increases, the more the sheets of current induced in the magnetic tubes are driven towards their outer skin.

Thus, it is demonstrated that the equivalent thickness of circulation of the current at the level of the outer skin can be defined by the expression: root (Kmaterial/f), with the current sheets encountering a resistance evolving as: 1/[root (Kmaterial/f)].

At the same time, the equivalent flux seen by the coil decreases, resulting in a decay law of the parallel equivalent inductance in 1/root (f).

The damping ratio (ksi) is then constant in a very wide frequency range and therefore very insensitive and subject to the variations in the value of the components interacting with the inductance L, as demonstrated by the following formula:

$$ξ = \frac{R d a m p i n g ( ω )}{2 \cdot L ( ω ) \cdot ω} with ω = 2 π F if \qquad [ Math 1 ]$$

$$Rdamping ( ω ) = K 1 \cdot \sqrt{ω} L ( ω ) and \qquad [ Math 2 ]$$

$$L ( ω ) = \frac{K 2}{\sqrt{ω}} , then \qquad [ Math 3 ]$$

$$ξ = \frac{K 1 \cdot \sqrt{ω}}{2 \cdot \frac{K 2}{\sqrt{ω}} \cdot ω} = \frac{K 1}{2 \cdot K 2} \qquad [ Math 4 ]$$

With ksi being the damping ratio, Rdamping being the damping resistance, K1 and K2 being two proportionality coefficients depending on the magnetic material, the geometric shapes and the number of turns.

FIGS. 2-2A illustrate, with a front view and a profile view, a first exemplary embodiment of the inductance L according to the aforementioned principle. The inductance 10 consists of a tube 12 made of magnetic material, typically made of ordinary magnetic steel whose resistivity and permeability are chosen based on the desired damping level and frequency range, on which an electrical conductor 14 of copper or aluminum is wound, and an insulating sheet 16, typically a Kapton® plastic film, separating the metal tube from the electrical conductor. To each of the two ends 14A, 14B of this electrical conductor is fixed a metal lug 18A, 18B forming one of the two end terminals (input and output electrical connections) of the inductance. It will be noted that, in one variant of embodiment not illustrated, the electrical conductor can be wound inside the magnetic material tube instead of being around it and the magnetic material tube can include a wall with slots or orifices.

A second exemplary embodiment of the inductance L according to the aforementioned principle is illustrated in FIG. 3. The inductance 20 is this time made up of several magnetic material tubes (here eight tubes 22A-22H without this number being limiting, a maximum number of 100 tubes being possible) identical or not identical and placed side by side in an insulating tube 26 on which the electrical conductor 24 is wound. The insulating tube, typically a tube made of PVC (polyvinyl chloride), polypropylene or epoxy resin for example, acts as a separator for the aforementioned insulating sheet. To each of the two ends 24A of the electrical conductor is fixed a metal lug 28A forming one of the two end terminals (input and output electrical connections) of the inductance. In the example illustrated, the magnetic material tubes are disposed side by side along the inner circumference of the insulating tube, leaving a central part empty of metal tubes which, by the possibility of air circulation it offers inside the PVC or polypropylene tube, has the advantage of facilitating the cooling of these heated metal tubes following the damping effect deliberately obtained by the eddy currents.

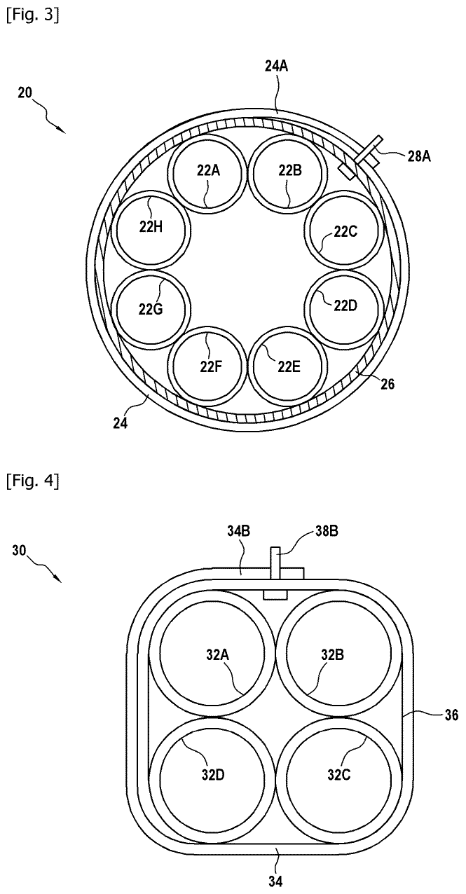

FIG. 4 illustrates a third exemplary embodiment of the inductance L according to the aforementioned principle. The inductance 30 is here made up of four magnetic material tubes 32A-32D, identical as illustrated or not identical, placed in parallel side by side and around which the electrical conductor 34 is wound, with an insulating sheet 36, typically a plastic film, separating the metal tubes from the electrical conductor. To each of the two ends 34B of this electrical conductor is fixed a metal lug 38B forming one of the two end terminals (input and output electrical connections) of the inductance. In this exemplary embodiment, the magnetic material tubes of circular profile and which are inscribed in a square are adjacent and do not leave room for another tube between them. However, it could be otherwise if these tubes had a different profile, for example square or polygonal.

Regardless of the exemplary embodiment chosen, the diameter (or the cross-section) of the magnetic material tube(s), their wall thickness, their length and the material used for the tube constituting the magnetic core are all parameters that can be adjusted to adapt and optimize the inductance to the desired application. An important parameter is the wall thickness that must be calculated such that the skin effect and therefore the damping are at the desired level in the desired frequency range where the LC filter is to operate.

It should be noted that, in one variant of embodiment not illustrated, the magnetic material tubes can be disposed around the wound electrical conductor instead of being inside it, and the walls of the magnetic material tubes can then include slots or orifices.

A prototype was made in accordance with the geometric configuration in FIG. 2 based on the following parameters: a 100 mm-long and 25.4 mm-diameter tube with a thickness of 1.5 mm and a weight of 85 g, made of ordinary magnetic steel with a resistivity of 1.383^{E}-007 and an initial relative magnetic permeability of 131; and a coil made up of 34 contiguous turns of a 2 mm-diameter copper conductor, for a coil weight of 125 g.

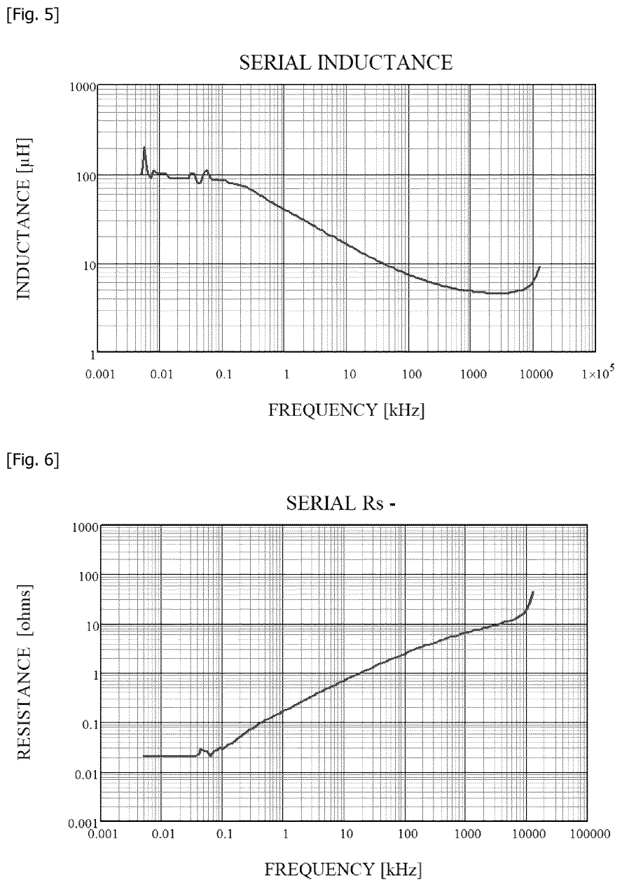

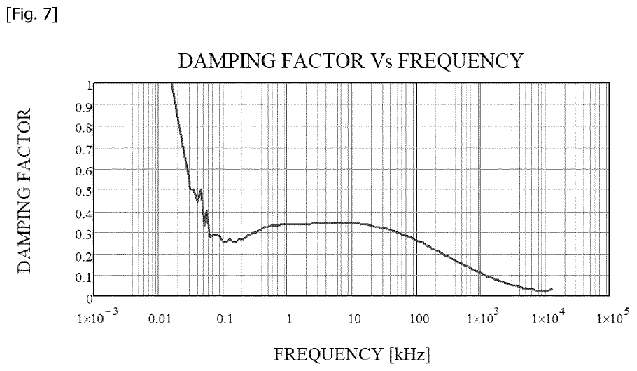

FIGS. 5, 6, and 7 show respectively, as a function of frequency, the equivalent serial inductance, the equivalent serial resistance and the damping ratio obtained with this magnetic loss inductance prototype. The variability in the root of the frequency of the equivalent serial inductance and the equivalent serial resistance can be clearly observed, as well as the desired stability of the damping ratio from 100 Hz to more than 100 KHz.

To determine these parameters, it is essential to have dedicated calculation means in order to adapt and optimize it for the envisaged application.

To do so, reference will be made to Maxwell's equations to lead to the following two basic relations: that of the reactive power Q exchanged with the magnetic circuit, and that of the active power P provided to this same magnetic circuit:

$$Q = π \cdot F \cdot {μ}_{0} \cdot {μ}_{r} \cdot Xw \cdot ( \frac{π \cdot {Dw}^{2}}{2} ) H {w}^{2} \cdot {Q}_{coeff} \qquad [ Math 5 ]$$

$$P = π \cdot F \cdot {μ}_{0} \cdot {μ}_{r} \cdot Xw \cdot ( \frac{π \cdot {Dw}^{2}}{2} ) H {w}^{2} \cdot {P}_{coeff} \qquad [ Math 6 ]$$

The coefficients Q_{coeff} and P_{coeff} are calculated as a function of the geometry of the magnetic circuit, the characteristics of the magnetic material and the penetration depth of the frequency-dependent current. For the most common shapes, such as a ring, these equations use Bessel-Kelvin functions.

By relying on: Q=Lsw*I², and P=Rs*I², those skilled in the art can easily determine the equivalent serial loss resistance and inductance and, through these calculations, confirm the curves obtained from the previous tests.

Thus, with the invention, it is possible to replace most conventional damping circuit LC filters with a magnetic loss inductance as described above, with the following advantages:
a single component replaces three, namely the inductance L of the LC filter, the power resistance and the inductance of the damping circuit, which means less wiring,
a considerable mass gain: for example for a converter of several tens of kW, associated with a conventional damping circuit, the weight reaches 2×1.05 kg (for a 0.2 damping), compared to 2×0.35 kg for the magnetic loss damping solution (for a damping from 0.27 to 0.4),
an absence of sensitivity to the accuracy of the components and to the manufacturing dispersion,
an absence of sensitivity to the network impedance variations due to a constant damping coefficient of the magnetic loss inductance over very wide frequency ranges,
easier cooling due to a winding disposed on the external wall,
a low manufacturing cost due to the raw materials used: ordinary magnetic steel, copper (or aluminum), insulator and a very simple manufacturing and assembly, ensuring a very high robustness, and
an ability to withstand high current overloads, the saturation level in terms of N*I being able to be raised very high, which proves advantageous in case of short circuit on the equipment itself and in case of short circuit upstream of the electrical network. Indeed, in the latter case, it is mainly the inductance of the input filter that limits the discharge current of the input capacitance in the short circuit. The risk, then, would be to destroy the protective member if the current reached excessively high levels (8,000 A to 10,000 A) following the saturation of this inductance. Maintaining the inductance at high current allows limiting the discharge current peak. The absence of saturation is an indirect consequence of the geometric choices of the inductance. The absence of rebounds in the decay phase of the short-circuit current is however directly linked to the self-damping ability.

1. An LC interfacing filter including a parallel capacitor and a serial inductance including eddy current magnetic losses, wherein that the inductance is configured so that the eddy current magnetic losses are at least 10 times greater than the hysteresis losses, and in that the inductance consists of a magnetic material tube, an electrical conductor being wound around or inside said magnetic material tube, with an insulating sheet separating the magnetic material tube from the electrical conductor over the entire surface of the magnetic material tube.

2. An LC interfacing filter including a parallel capacitor and a serial inductance including eddy current magnetic losses, characterized in that the inductance is configured so that the eddy current magnetic losses are at least 10 times greater than the hysteresis losses and in that the inductance consists of several magnetic material tubes placed side by side, an electrical conductor being wound around or inside said magnetic material tubes, with an insulating tube or an insulating sheet separating the magnetic material tubes from the electrical conductor.

3. The LC interfacing filter according to claim 2, wherein the number of magnetic material tubes is comprised between 2 and 100.

4. The LC interfacing filter according to claim 2, wherein the magnetic material tubes are identical.

5. The LC interfacing filter according to claim 1, wherein the magnetic material tubes each include a wall with slots or orifices.

6. The LC interfacing filter according to claim 1, wherein the magnetic material tube(s) each have a circular, square or polygonal profile.

7. An electrical supply network including an LC interfacing filter according to claim 1.
